(19) United States
(12) Patent Application Publication
(10) Pub. No.: US 2004/0038451 A1
(43) Pub. Date: Feb. 26, 2004

(54) Method suitable for forming a microelectronic device package

(76) Inventors: Douglas A. Hawks, San Diego, CA (US); Siamak Fazelpour, Irvine, CA (US); Robbie Villanueva, Rancho Santa Margarita, CA (US)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 10/649,577

(22) Filed: Aug. 26, 2003

Related U.S. Application Data
(62) Division of application No. 09/413,552, filed on Oct. 6, 1999.

(51) Int. Cl. H01L 21/44

(52) U.S. Cl. 438/110; 438/106; 438/124

(57) ABSTRACT

Methods for forming the package are disclosed. The device package includes electrical connectors and an encapsulant. The package is formed by placing removable material over a portion of the connectors to prevent encapsulant attachment to the portions masked by the removable material.

### CROSS-REFERENCE TO RELATED APPLICATION

This application is a divisional of copending U.S. utility application entitled, “Method and Apparatus Suitable for Forming a Microelectronic Device Package,” having Ser. No. 09/413,552, filed Oct. 6, 1999, which is entirely incorporated herein by reference.

### FIELD OF THE INVENTION

The present invention generally relates to microelectronic device packages. More particularly, the present invention relates to improved frame-based packages and methods for forming the packages.

### BACKGROUND OF THE INVENTION

Microelectronic devices such as semiconductor devices are often packaged to protect the device from mechanical damage, chemical attack, light, extreme temperature cycles, and other environmental effects. In addition, the devices are often packaged to facilitate attachment of the device to a substrate such as a printed circuit board. In particular, the device package may facilitate attachment of the device to a substrate by providing mechanical support during the attachment process and by providing electrical connections between the device and the substrate.

Packages for providing electrical connections between various electrical devices and a substrate and methods for forming the packages are generally known in the art. For example, use of ball grid array packages, land grid array packages, and leadframe-based packages as well as methods of forming packaged devices with the various forms of packages are generally known in the art.

Compared to other forms of microelectronic device packages, leadframe packages may be advantageous for several reasons. For example, leadframe packages are relatively inexpensive, are relatively reliable, do not require an additional substrate, and methods for forming typical leadframe packages are relatively well understood. However, as discussed in more detail below, packaged electronic devices including typical leadframes may be problematic for several reasons.

In particular, leadframe packages have relatively few electrical connections between the device and the substrate, whereas packages using ball grid array, land grid array, and similar technologies allow for a relatively high number of electrical connections between the device and the substrate. In other words, these technologies allow electrical connection between a device having a relatively high input/output count and the substrate.

Leadframe-based microelectronic devices packages generally include (1) a leadframe to support the device and facilitate electrical connections between the device and the substrate and (2) an encapsulant to protect the device and a portion of the leadframe from the environment. The leadframe is formed of conductive material (e.g., a thin sheet of metal such as copper) and includes a pad or paddle portion configured to receive various electronic components and leads that are configured to mechanically and/or electrically couple the device to the substrate.

A typical leadframe includes a single row of leads that span outwardly from the paddle region of the leadframe. Although this configuration facilitates electrical connections between the microelectronic device and the substrate, the number of electrical connections between the device and the substrate is limited by the number of leads that may be formed about the perimeter of the paddle. Other device packages such as ball grid array and land grid array packages allow for multiple rows or a matrix of conductive connectors about the paddle perimeter, but packages including such a matrix of conductive connectors are relatively expensive compared to packages including a leadframe. Accordingly, improved, relatively inexpensive, device packages that allow more than a single row of conductive connectors to be formed about a device are desired.

A typical packaged device having a leadframe is formed by attaching a microelectronic device to the paddle of the leadframe, attaching wire bonds between portions of the device (e.g., input/output contacts on the device) and the conductive leads of the leadframe, and encapsulating the device, paddle, wire bonds, and a portion of the conductive leads.

Encapsulating the entire paddle may be problematic in several regards, First, excess encapsulant is required to encapsulate the entire paddle. Excess encapsulant unnecessarily increases the size and cost of the packaged device. Second, encapsulating the entire paddle generally increases the lead length required to form an electrical connection between the device and the substrate. Increased lead length increases undesirable parasitics such as inductance and capacitance along the conductive path between the device and the substrate. Third, encapsulating the entire paddle inhibits grounding the device to the substrate using the paddle as a conductive path. For, inter alia, the reasons set forth above, an improved frame-based microelectronic device package having less encapsulant, at least a portion of a leadframe paddle exposed, and a reduced conductive path length between the device and the substrate is desirable.

### SUMMARY OF THE INVENTION

The present invention provides an improved package for one or more microelectronic devices and methods for forming the device package. More particularly, the present invention provides an improved frame-based device package and methods for forming the package.

The manner in which the present invention addresses the drawbacks of presently-known device packages is addressed in greater detail hereinbelow. However, in general, the improved package is relatively inexpensive to manufacture, and can support devices having relatively high input/output counts.

In accordance with an embodiment of the present invention, a device package is formed by attaching removable tape to a surface of a film of conductive material, forming isolated features in the conductive material, attaching encapsulating material to at least a portion of the isolated features and a portion of the tape, and removing the tape from the features and encapsulant. In accordance with an aspect of this embodiment, the features are formed by patterning the conductive material with photoresist material and etching the material to form the isolated features.

### BRIEF DESCRIPTION OF THE DRAWINGS

A more complete understanding of the present invention may be derived by referring to the detailed description and claims, considered in connection with the figures, wherein like reference numbers refer to similar elements throughout the figures.

FIG. 1 illustrates a cross-sectional view of a device package in accordance with the present invention.

FIG. 2 illustrates a process to form a device package in accordance with the present invention.

FIG. 3 illustrates a flame having tape attached thereto in accordance with the present invention.

FIG. 4 illustrates a patterned, etched flame, having tape attached thereto in accordance with the present invention.

FIG. 5 illustrates a portion of a device package during package fabrication in accordance with the present invention.

FIG. 6 illustrates a top plan view of a portion of a package during package fabrication in accordance with the present invention.

FIG. 7 illustrates a top plan view of a portion of a package during package fabrication in accordance with an alternative embodiment of the present invention.

FIG. 8 illustrates a device package having tape attached thereto during package fabrication in accordance with the present invention.

### DETAILED DESCRIPTION OF EXEMPLARY EMBODIMENTS

The present invention provides an improved microelectronic device package. While the present invention may be used to couple a plurality of electronic devices to a substrate, the invention is conveniently described hereinbelow with a single packaged device suitable for coupling to the substrate.

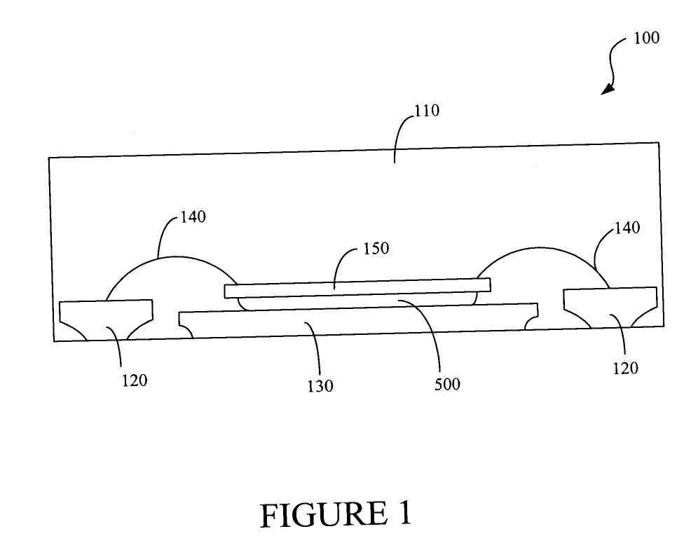

FIG. 1 illustrates a cross-sectional view of a packaged device 100 in accordance with the present invention. Packaged device 100 generally includes an encapsulant 110, a connector 120, abase or die attach pad 130, a wire 140, and a device 150.

Encapsulant 110 may be formed of any material that protects device 150, For example, encapsulant 110 may include thermoplastics, reaction injection molding materials, or the like. However, in accordance with an exemplary embodiment of the present invention, encapsulant 110 includes a thermoset moldable plastic compound such as epoxy resin.

Connector 120 may be formed of any conductive material. In accordance with an exemplary embodiment of the present invention, connector 120 is formed of copper. However, in accordance with alternative embodiments of the present invention, conductor 120 may be formed of other conductive material such as alloy 42.

As discussed in greater detail below, in accordance with an exemplary embodiment of the present invention, connector 120 is formed from a metal frame (e.g., a metal sheet or a leadframe). While the frame composition and thickness may vary from application to application, in accordance with an exemplary embodiment of the present invention, the frame is formed of a copper metal sheet having a thickness of approximately 200 microns. The metal frame may be coated with about 10 micro inches of palladium to facilitate electrical and/or mechanical attachment of wire 140 to connector 120 and electrical and/or mechanical attachment of connector 120 to a substrate (not shown).

Unlike conventional leads of a leadframe-based package, connector 120 is not formed or bent. Thus fewer processing steps are required to produce connector 120 than are required to form leads of a leadframe. In addition, the conductive path from device 150, through wire 140 and connector 120, is significantly shorter through packaged device 100 than through typical packaged devices using conventional leadframes. The conductive path is shorter, in part, because the conductive path length through connector 120 is the thickness of connector 120 (e.g., about 200 microns), whereas with conventional leadframe packages, the conductive length through a lead is the length of the lead, which may be on the order of a few millimeters. Reduction of the conductive path length reduces the package device parasitics such as inductance and capacitance along the conductive path and reduces the overall size of packaged device 100.

Base 130 may be formed of any material suitable for attaching to device 150. In accordance with an exemplary embodiment of the present invention, base 130 is formed of the same material used to form connector 120 (e.g., copper metal). In accordance with an exemplary embodiment of the present invention, connector 120 and base 130 are formed from a single sheet of conductive material such as a metal frame used to form conventional leadframes.

In accordance with an exemplary embodiment of the present invention, unlike typical leadframe-based packages, base 130 is not offset or downset from connectors 120. Although base 130 is not offset from connectors 120, the conductive path between device 150 and the substrate is significantly shorter for packaged device 100 than for typical leadframe-based packages, for the reasons noted above.

Wire 140 may be formed of any material suitable for electrically coupling connector 120 to a portion of device 150. In accordance with an exemplary embodiment of the present invention, wire 140 is formed of gold wire having a diameter of approximately 25 μm.

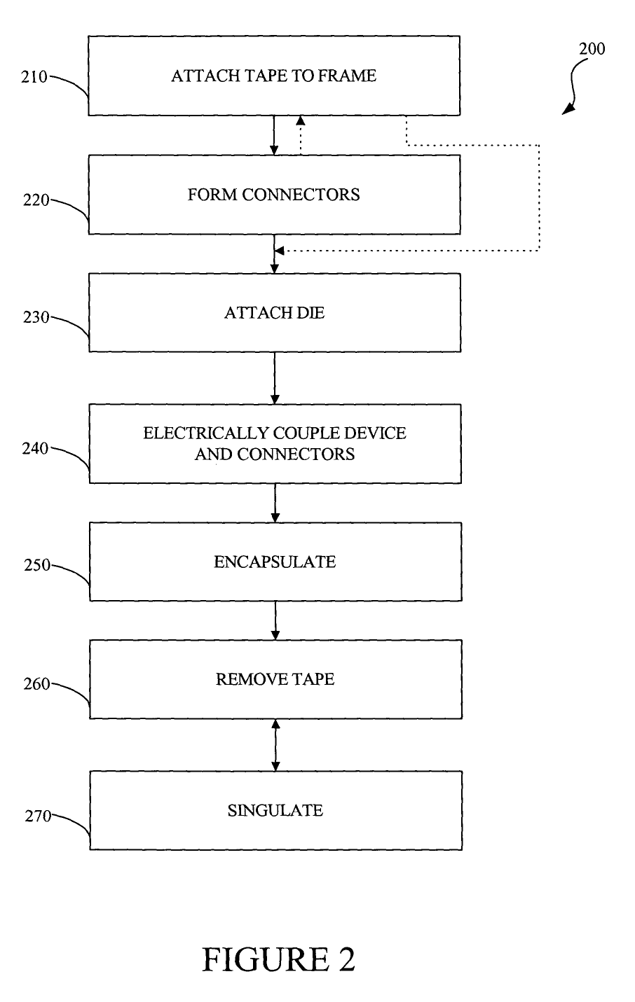

Packaged device 100 may be formed in accordance with an exemplary process 200, which is schematically illustrated in FIG. 2. Process 200 suitably includes a tape attach step 210, a conductive feature formation step 220, a die attach step 230, an electrically coupling step 240, an encapsulating step 250, a tape removal step 260, and a singulation step 270. As discussed in more detail below, the order of various steps in process 200 may be changed, depending on, among other things, the type of frame used to form packaged device 100.

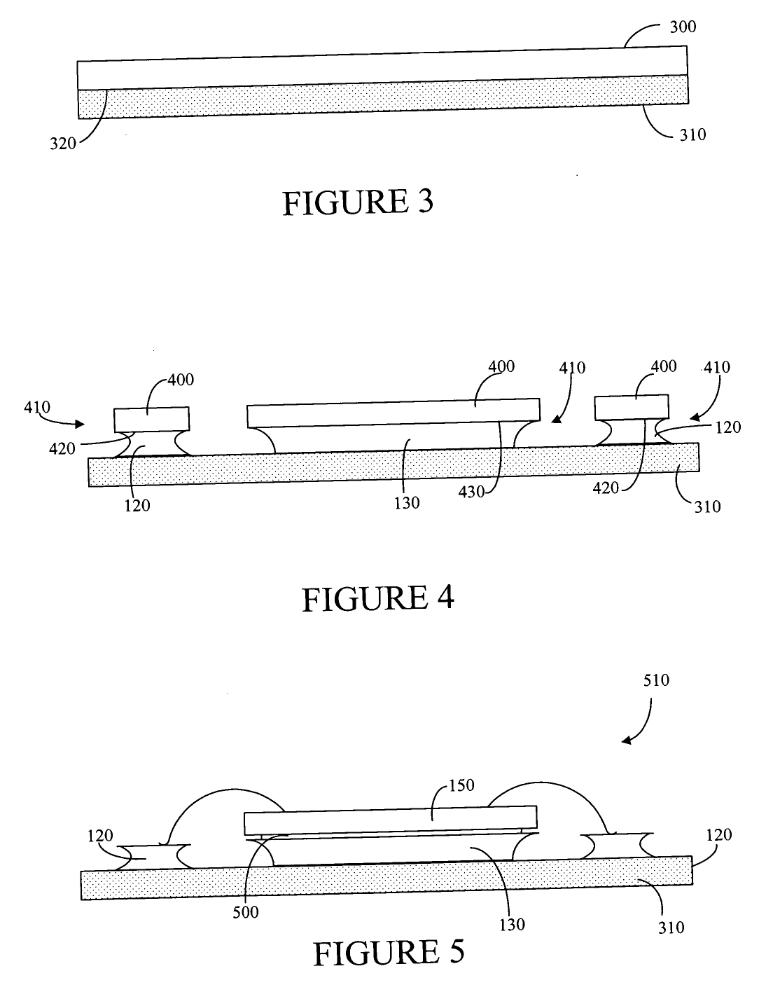

FIG. 3 illustrates a metal frame 300 having a removable tape 310 attached thereto after completion of tape attach step 210. Tape 310 is generally configured to prevent adhesion of encapsulant 110 to a bottom surface 320 of frame 300. Although tape 310 may be formed of various materials that removably attach to frame 300, in accordance with an exemplary embodiment of the present invention, tape 300 comprises a polyimide material and a water soluble adhesive. For example, a 3M Corporation adhesive tape 5414 may be used in connection with the present invention to prevent encapsulant 110 adhesion to surface 320.

During step 210, tape 310 may be applied to frame 300 using any manual or automated process. In accordance with an exemplary embodiment of the present invention, tape 310 is applied to a surface 320 of frame 300 using an automatic taping machine with a water soluble adhesive. Tape 310 may be configured to cover any amount of surface 320, and in accordance with an exemplary aspect of the embodiment illustrated in FIG. 3, tape 310 covers substantially the entire bottom surface 320 of frame 300.

During conductive feature formation step 220, electrical connectors 120 and base 130 are formed. In accordance with an exemplary embodiment of the present invention, features 120 and 130 are formed by patterning a surface of frame 300 and etching portions of frame 300 through to tape 310.

FIG. 4 illustrates a frame 300 patterned and etched to form conductive features (e.g., connector 120 and base 130). In accordance with an exemplary embodiment of the present invention, frame 300 is patterned with material resistant to the etchant used to etch frame 300, such as photoresist 400. Frame 300 is then suitably etched using any material that reacts with frame 300 to dissolve or form volatile compounds with frame 300 material In accordance with an exemplary embodiment of the present invention, frame 300 is etched using an isotropic wet process. Use of a wet process or other isotropic etchants is advantageous because the isotropic etchant may be used to form an undercut region 410. Formation of undercut region 410 may be desirable because region 410 provides a greater adhesion surface area for encapsulant 110 to bond to features 120, 130, and region 410 provides lip areas 420 and 430 to assist attachment of encapsulant 110 to features 120 and 130. After features 120 and 130 are formed, photoresist 400 is removed using any suitable solvent, and features 120, 130 maybe cleaned as desired.

In accordance with an alternative embodiment of the present invention, frame 300 includes a leadframe with the die attach region and lead regions already defined either by stamping or etching a sheet of conductive material (e,g., a sheet of copper metal). In accordance with this embodiment, after the die attach and lead regions are manufactured, frame 300 is exposed to an etchant to form regions 410 and lip areas 420, 430 as described above. This etch may be performed prior to or after tape 310 is applied to frame 300. In accordance with this embodiment, connector formation step 220 is performed prior to performing tape attachment step 210.

Using a leadframe as frame 300 maybe advantageous because connectors 120 of a leadframe are generally coupled to other portions of frame 300 until frame 300 is exposed to singulation step 270. Coupling of connectors 120 may be advantageous because the coupling increases the stiffness of frame 300, which may be advantageous during packaged device 100 formation. However, use of a leadframe such as frame 300 may be disadvantageous because only a single row of connectors 120 maybe formed about pad 130, whereas multiple rows or a matrix of connectors 120 may be formed about the perimeter of pad 130 when a metal sheet is used as frame 300.

At die attach step 230, one or more electrical components (e.g., device 150) are mechanically coupled to base 130 using an adhesive material such as epoxy. In accordance with an exemplary embodiment of the present invention illustrated in FIG. 5, device 150 is attached to base 130 using a conductive epoxy 500. Use of conductive epoxy 500 to bond device 150 to base 130 is advantageous because it allows portions of device 150 to electrically couple to base 130, thus allowing the device to ground to a substrate through base 130 and conduct heat to base 130.

A portion of device 150 and connector 120 are electrically coupled during coupling step 240. In accordance with an exemplary embodiment of the present invention, device 150 and connector 120 are electrically coupled by attaching a portion of wire 140 to device 150 and a portion of wire 140 to connector 120. Wire 140 maybe attached to device 150 and connector 120 using any wire bonding technique.

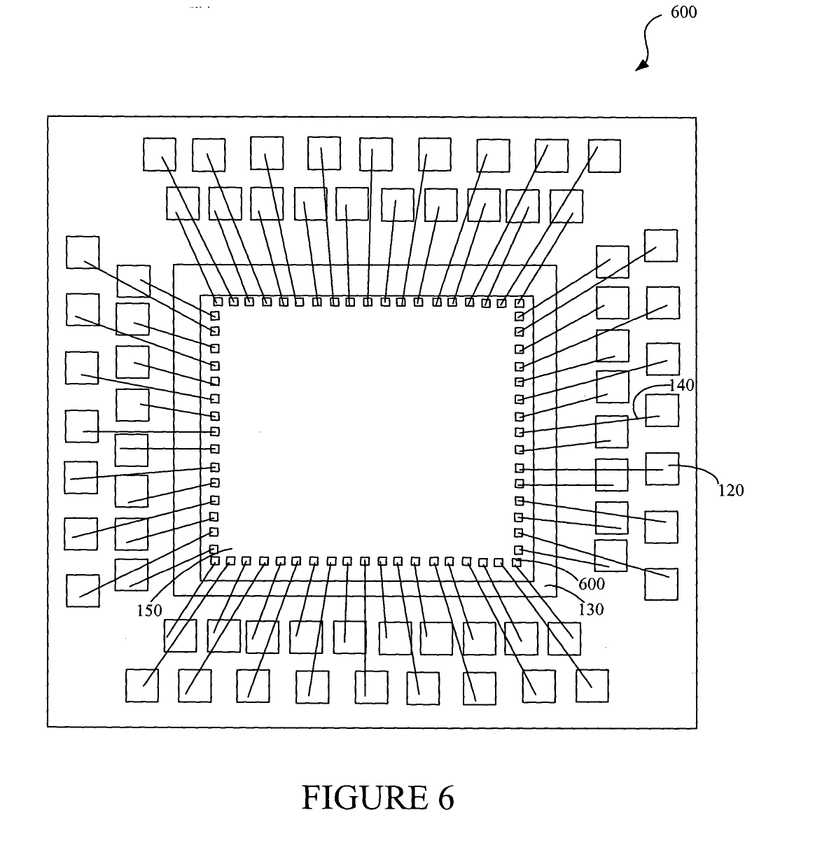

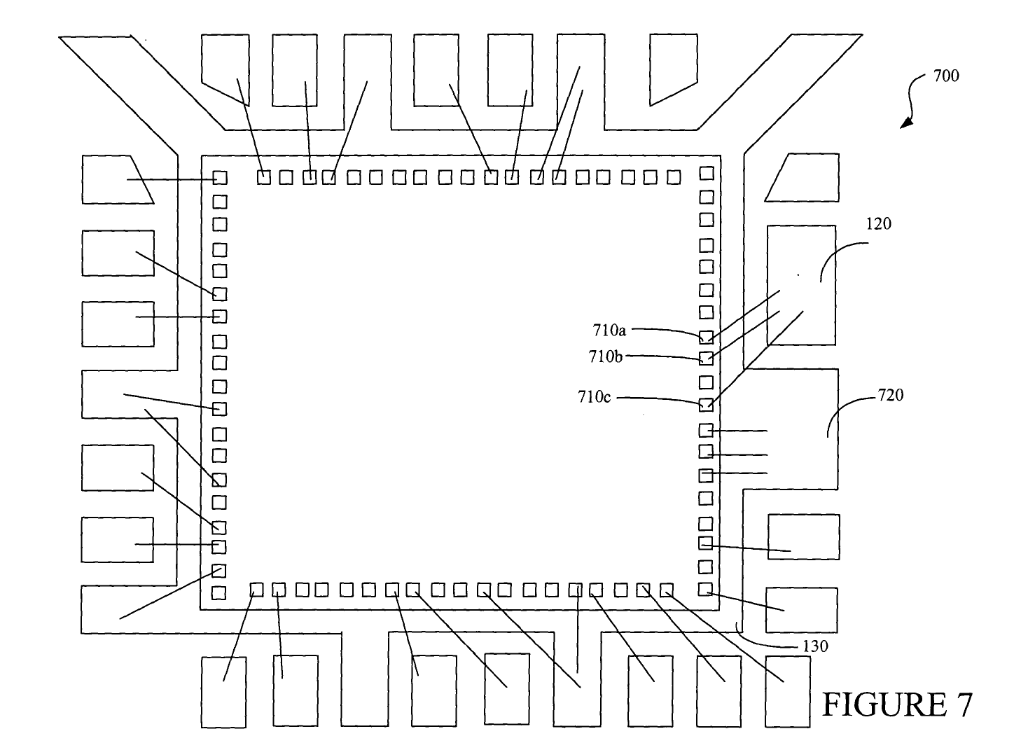

FIGS. 6 and 7 illustrate top plan views of exemplary packages 600 and 700, respectively, after completion of step 240. Package 600 includes a matrix of two rows of connectors 120 formed of a metal sheet frame, while package 700 includes only a single row of connectors 120 about a perimeter of device 150 formed of a leadframe. Additional rows of connectors 120 allow additional electrical connections between device 150 and the substrate (not shown), permitting electrical connections between relatively high input/output count devices and the substrate. Although FIG. 6 illustrates only two rows of connectors 120, it should be appreciated that any number and any configuration (e.g., size and/or shape) of connectors 120 may be used in accordance with the present invention. Thus, the present invention provides a device package which allows for high input/output counts similar to input/output counts of land grid array and ball grid array modules, without requiring relatively complex, expensive processing typical of packages formed from such modules.

During electrical coupling step 240, any number of input/output regions 610, 710 may be coupled to any number of connectors 120. For example, as illustrated in FIG. 7, three device input/output regions 710a, 710b, and 710c may be coupled to a single connector 120. In addition, multiple input/output regions 710 may be connected to a conductive region 720 that is coupled to base 130. Coupling various input/output regions 710 to region 720 may facilitate the grounding of respective regions 710.

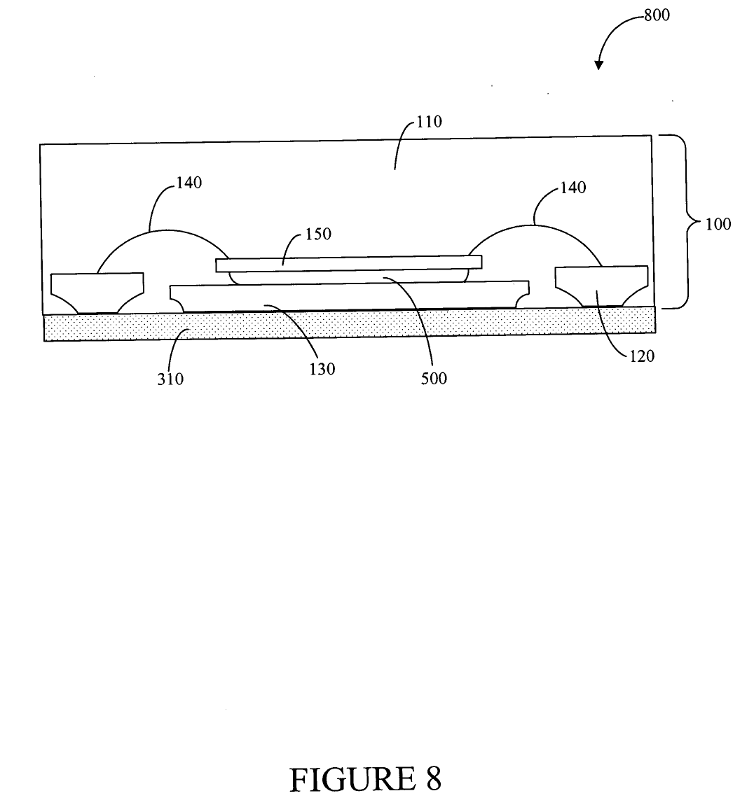

Encapsulating step 250 generally involves placing a mold around structure 510, and forming a molded encapsulant 110 around portion 510 to form structure 800, illustrated in FIG. 8. In accordance with an exemplary embodiment of the present invention, step 250 includes molding an epoxy resin compound about a top surface of portion 510 to form structure 800.

Finally, packaged device 100 may be formed by removing tape 310 during step 260 and singulating devices 100 during step 270. Steps 260 and 270 may be performed in any order; the sequence of steps may depend on the type of tape 310 used to form device 100 and the type of singulation process used to separate individual packaged devices 100.

In accordance with an exemplary embodiment of the present invention, tape 310 is removed during step 260 by immersing tape 310 in hot (e.g., 60° C.) water. Any residual adhesive may be removed, if desired, by exposing surface 320 to a solvent such as deionized water.

Singulation step 270 may be performed using any process suitable for separating individual packaged devices 100. In accordance with an exemplary embodiment of the present invention, packaged devices 100 are separated by sawing between individual packaged devices 100. When frame 300 includes a leadframe, singulation step 270 decouples connectors 120 to form isolated conductive features.

Although the present invention is set forth herein in the context of the appended drawing figures, it should be appreciated that the invention is not limited to the specific form shown. For example, while the illustrated exemplary method to form the device package includes applying tape to a bottom surface of a frame, any suitable removable material such as a mold stencil that is attached to the leadframe using a soluble adhesive may be used to prevent adhesion of encapsulant to a surface of the frame. Various other modifications, variations, and enhancements in the design and arrangement of the device package as set forth herein may be made without departing from the spirit and scope of the present invention as set forth in the appended claims.

What is claimed is:

1. A method for forming a package for an electrical device, said method comprising the steps of
attaching a removable material to a surface of a conductive material;
forming isolated conductive features within said conductive material;
attaching encapsulant to said isolated conductive features and said removable material; and
removing said removable material from said conductive features and said encapsulant.

2. The method for forming a package for the electronic device of claim 1, wherein said forming step includes patterning a surface of said conductive material with a material resistant to an etchant and etching said conductive material with said etchant.

3. The method for forming a package for the electronic device of claim 1, further comprising the step of forming a die attach pad within said conductive material.

4. The method for forming a package for the electronic device of claim 1, further comprising the step of coupling the device to said die attach pad.

5. The method for forming a package for an electronic device of claim 1, further comprising the step of electrically coupling an input/output portion of the device to said isolated conductive feature.

6. The method for forming a package for the electronic device of claim 1, further comprising the step of singulating individual packaged devices.

7. The method of claim 1, wherein the removable material is water soluble adhesive.

8. The method of claim 7, wherein the removable material is removed with deionized water.

9. A method of forming a device package, said method comprising the steps of:
applying removable material to a leadframe;
attaching a device to said leadframe; and
attaching encapsulant to a portion of said device and a portion of said leadframe.

10. The method of forming a device package according to claim 9, further comprising the step of exposing said leadframe to an etchant to form undercut regions configured to assist attachment of said encapsulant to said leadframe.

11. The method of forming a device package according to claim 9, further comprising the step of electrically coupling a portion of said device to said leadframe.

12. The method of forming a device package according to claim 9, further comprising the step of forming isolated conductive features by sawing through a portion of said leadframe.

13. The method of forming a device package according to claim 9, further comprising the step of removing said removable material from said leadframe and said encapsulant.

14. The method of claim 9, wherein the removable material is water soluble adhesive.

15. The method of claim 14, wherein the removable material is removed with deionized water.
